(19) United States
(12) Patent Application Publication
(10) Pub. No.: US 2025/0227973 A1
(43) Pub. Date: Jul. 10, 2025

(54) SEMICONDUCTOR SUBSTRATE, TEMPLATE SUBSTRATE, AND MANUFACTURING METHOD AND MANUFACTURING APPARATUS OF SEMICONDUCTOR SUBSTRATE

(71) Applicant: KYOCERA CORPORATION, Kyoto-shi, Kyoto (JP)

(72) Inventors: Yuichiro HAYASHI, Kyoto-shi (JP); Katsuaki MASAKI, Kyoto-shi (JP); Takeshi KAMIKAWA, Kyoto-shi (JP)

(73) Assignee: KYOCERA CORPORATION, Kyoto-shi, Kyoto (JP)

(21) Appl. No.: 18/850,793

(22) PCT Filed: Mar. 22, 2023
(86) PCT No.: PCT/JP2023/011064

§ 371 Date: Sep. 25, 2024

(30) Foreign Application Priority Data
Mar. 28, 2022 (JP) 2022-052494

(51) Int. Cl. H10D 62/85; H10D 62/10; H10D 62/40

(52) U.S. Cl. CPC H10D 62/8503; H10D 62/117; H10D 62/405

(57) ABSTRACT

A semiconductor substrate includes: a template substrate including a base substrate including crystal different from a nitride semiconductor crystal in lattice constant, the template substrate including a growth suppression region, a first seed region being independent and having a first direction being a longitudinal direction, and a second seed region being independent and having a second direction, different from the first direction, being a longitudinal direction; a first nitride semiconductor portion having an island-shape and disposed to extend from the first seed region upward beyond the growth suppression region; and a second nitride semiconductor portion having an island-shape and disposed to extend from the second seed region upward beyond the growth suppression region.

### TECHNICAL FIELD

The present disclosure relates to a semiconductor substrate and the like.

### BACKGROUND OF INVENTION

Patent Document 1 discloses a technique for forming a GaN-based semiconductor layer on a heterogeneous substrate (for example, a sapphire substrate) by using an epitaxial lateral overgrowth (ELO) method.

### CITATION LIST

### Patent Literature

Patent Document 1: JP 2013-251304 A

### SUMMARY

A semiconductor substrate according to the present disclosure includes: a template substrate including a base substrate including a substrate material that is not a nitride semiconductor, the template substrate including a growth suppression region, a first seed region being independent and having a first direction being a longitudinal direction, and a second seed region being independent and having a second direction, different from the first direction, being a longitudinal direction; a first nitride semiconductor portion having an island-shape and disposed to extend from the first seed region upward beyond the growth suppression region; and a second nitride semiconductor portion having an island-shape and disposed to extend from the second seed region upward beyond the growth suppression region.

### BRIEF DESCRIPTION OF THE DRAWINGS

FIG. 1 is a plan view illustrating a configuration example of a semiconductor substrate according to the present embodiment.

FIG. 2 is an enlarged plan view of a part of FIG. 1.

FIG. 3A is a cross-sectional view illustrating a configuration example of the semiconductor substrate according to the present embodiment.

FIG. 3B is a cross-sectional view illustrating a configuration example of the semiconductor substrate according to the present embodiment.

FIG. 3C is a cross-sectional view illustrating the configuration example of a semiconductor substrate according to the present embodiment.

FIG. 4 is a cross-sectional view illustrating another example of the semiconductor substrate according to the present embodiment.

FIG. 5 is an enlarged plan view of a part of FIG. 2.

FIG. 6 is a plan view illustrating another configuration example of the semiconductor substrate according to the present embodiment.

FIG. 7 is an enlarged plan view of a part of FIG. 6.

FIG. 8 is a plan view illustrating another configuration example of the semiconductor substrate according to the present embodiment.

FIG. 9 is an enlarged plan view of a part of FIG. 8.

FIG. 10 is a plan view illustrating another configuration example of the semiconductor substrate according to the present embodiment.

FIG. 11 is an enlarged plan view of a part of FIG. 10.

FIG. 12 is a plan view illustrating another configuration example of the semiconductor substrate according to the present embodiment.

FIG. 13 is an enlarged plan view of a part of FIG. 12.

FIG. 14 is a plan view illustrating another configuration example of the semiconductor substrate according to the present embodiment.

FIG. 15 is an enlarged plan view of a part of FIG. 14.

FIG. 16 is a plan view illustrating a configuration example of a template substrate according to the present embodiment.

FIG. 17 is an enlarged plan view of a part of FIG. 16.

FIG. 18 is a cross-sectional view illustrating a configuration example of the template substrate according to the present embodiment.

FIG. 19 is a cross-sectional view illustrating a configuration example of the template substrate according to the present embodiment.

FIG. 20 is a flowchart illustrating a manufacturing method of the semiconductor substrate according to the present embodiment.

FIG. 21 is a block diagram illustrating a manufacturing apparatus of the semiconductor substrate according to the present embodiment.

FIG. 22 is a schematic view illustrating a configuration of a nitride semiconductor forming apparatus according to the present embodiment.

FIG. 23 is a cross-sectional view illustrating a configuration example of a base substrate.

FIG. 24 is a cross-sectional view illustrating a manufacturing method of a semiconductor substrate according to Example 1.

FIG. 25 is a cross-sectional view illustrating a manufacturing method of a semiconductor element according to Example 2.

FIG. 26 is a plan view illustrating the manufacturing method of the semiconductor element according to Example 2.

FIG. 27 is a cross-sectional view illustrating the configuration example of a semiconductor substrate according to the present embodiment.

### DESCRIPTION OF EMBODIMENTS

### Semiconductor Substrate

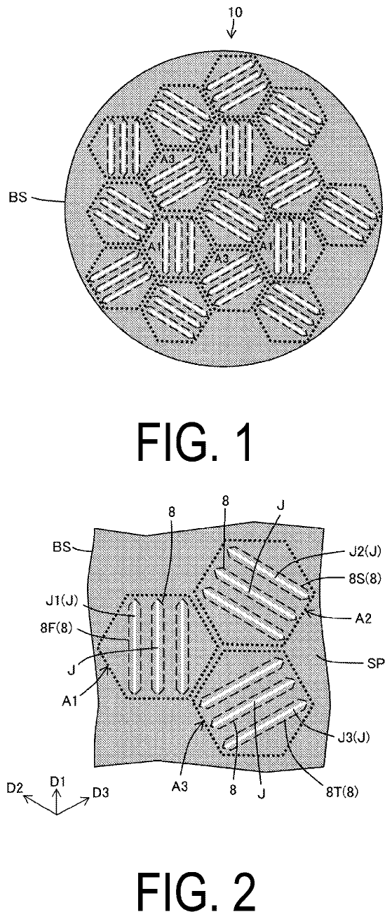

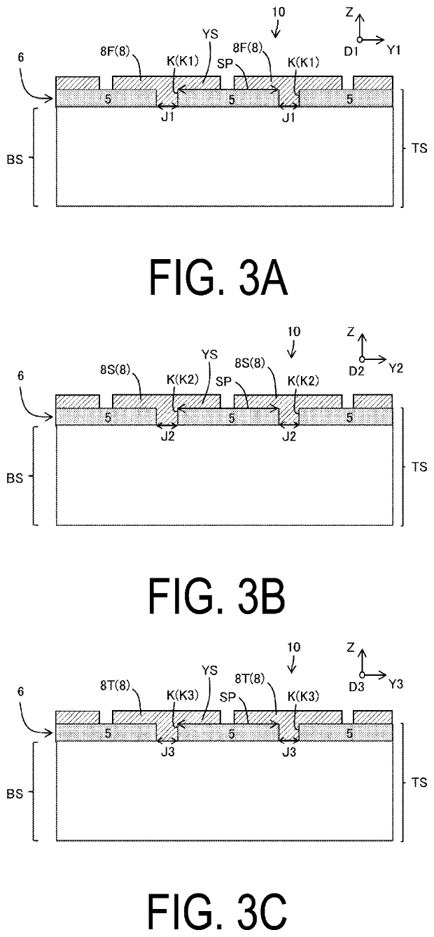

FIG. 1 is a plan view illustrating a configuration example of a semiconductor substrate according to the present embodiment. FIG. 2 is an enlarged plan view of a part of FIG. 1. FIG. 3A to FIG. 3C are cross-sectional views illustrating the configuration example of the semiconductor substrate according to the present embodiment. As illustrated in FIG. 1, FIG. 2, and FIGS. 3A to 3C, a semiconductor substrate 10 (semiconductor wafer) according to the present embodiment includes: a template substrate TS including a base substrate BS including a substrate material that is not a nitride semiconductor, as well as (i) a growth suppression region SP, (ii) an independent first seed region J1 with a first direction D1 being a longitudinal direction, and (iii) an independent second seed region J2 with a second direction D2, different from the first direction D1, being a longitudinal direction; an island-shaped first nitride semiconductor portion 8F disposed to extend from the first seed region J1 upward beyond the growth suppression region SP; and an island-shaped second nitride semiconductor portion 8S disposed to extend from the second seed region J2 upward beyond the growth suppression region SP. The first and second directions D1 and D2 are, for example, different directions on a plane parallel to the base substrate BS. On this plane, a direction orthogonal to the first direction D1 is denoted by Y1, a direction orthogonal to the second direction D2 is denoted by Y2, and a normal direction of this plane (a thickness direction of the first and second nitride semiconductor portions 8F and 8S) is denoted by Z.

As illustrated in FIGS. 3A and 3B, in the semiconductor substrate 10, the template substrate TS may have on the base substrate BS, a mask portion 5 and a mask pattern 6 including a first opening portion K1 and a second opening portion K2, the growth suppression region SP may be an upper surface of the mask portion 5, and the base substrate BS may have an upper surface including the first seed region J1 overlapping the first opening portion K1 and the second seed region J2 overlapping the second opening portion K2. Hereinafter, seed regions including the first and second seed regions J1 and J2 are collectively referred to as a seed region J, opening portions of the mask pattern 6 including the first and second opening portions K1 and K2 are collectively referred to as an opening portion K, and nitride semiconductor portions including the first and second nitride semiconductor portions 8F and 8S are collectively referred to as a nitride semiconductor portion 8. The mask pattern 6 may be a mask layer and the nitride semiconductor portion 8 may be a nitride semiconductor layer. In the semiconductor substrate 10, a direction from the base substrate BS to the nitride semiconductor portion 8 is referred to as an “upward direction”. Viewing an object with a line of sight parallel to a normal direction of the semiconductor substrate 10 (including viewing an object in a perspective manner) is referred to as “plan view”.

The nitride semiconductor portion 8 contains a nitride semiconductor as a main material. The nitride semiconductor may be a group III-V semiconductor and may be expressed as, for example, AlxGayInzN (0≤x≤1; 0≤y≤1; 0≤z≤1; x+y+z=1). Specific examples of the nitride semiconductor include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor may include GaN, AlGaN, AlGaInN, and InGaN.

The nitride semiconductor portion 8 may be of a doped type (for example, n-type including a donor) or a non-doped type. The semiconductor substrate means a substrate including a nitride semiconductor, and the base substrate BS may include a semiconductor (for example, a silicon, silicon carbide, and the like) other than a nitride semiconductor or a non-semiconductor. The base substrate BS and the mask pattern 6 may be collectively referred to as a template substrate TS.

The first nitride semiconductor portion 8F can be formed by an epitaxial lateral overgrowth (ELO) method with the first seed region J1 (the upper surface of the base substrate BS exposed from the first opening portion K1) being the starting point. The first direction D1 may be an m-axis direction (<1-100> direction) of the first nitride semiconductor portion 8F. A width direction of the first seed region J1 (direction Y1 orthogonal to the first direction D1) may be an a-axis direction (<11-20> direction) of the first nitride semiconductor portion 8F. A thickness direction Z of the first nitride semiconductor portion 8F may be a c-axis direction (<0001> direction).

The second nitride semiconductor portion 8S can be formed by the ELO method with the second seed region J2 (the upper surface of the base substrate BS exposed from the first opening portion K1) being the starting point. The second direction D2 may be the m-axis direction (<1-100> direction) of the second nitride semiconductor portion 8S. A width direction of the second seed region J2 (direction Y2 orthogonal to the second direction D2) may be the a-axis direction (<11-20> direction) of the second nitride semiconductor portion 8S. The thickness direction Z of the second nitride semiconductor portion 8S may be the c-axis direction (<0001> direction).

In the nitride semiconductor portion 8 (8F/8S), a portion located above the seed region J serves as a dislocation inheritance portion with a larger number of threading dislocations, and a portion (wing portion on the mask portion 5) located above the growth suppression region SP serves as a low-defect portion YS with a lower threading dislocation density than the dislocation inheritance portion.

As illustrated in FIGS. 1 and 2, with the longitudinal directions of the first and second seed regions J1 and J2 being different from each other, the first and second nitride semiconductor portions 8F and 8S extend in different directions, whereby the warpage of the semiconductor substrate 10 due to a difference in the nitride semiconductor portion 8 and the base substrate BS in thermal expansion coefficient can be reduced. The substrate material (non-nitride semiconductor) included in the base substrate BS may have a smaller thermal expansion coefficient than that of the nitride semiconductor (for example, GaN).

Each of the first and second nitride semiconductor portions 8F and 8S may be a hexagonal crystal, and the first direction D1 and the second direction D2 may form an acute angle of 60 degrees.

The template substrate TS may include: one or more first unit regions A1 in which a plurality of the independent seed regions J including the first seed region J1 with the first direction D1 being a longitudinal direction are arranged; and one or more second unit regions A2 in which a plurality of the independent seed regions J including the second seed region J2 with the second direction D2 being a longitudinal direction are arranged.

In the template substrate TS, as illustrated in FIG. 1, the plurality of first unit regions A1 may be dispersedly arranged in a plane, and the plurality of second unit regions A2 may be dispersedly arranged in the plane. The plurality of first unit regions A1 and the plurality of second unit regions A2 may be arranged without the first unit regions A1 being adjacent to each other and without the second unit regions A2 being adjacent to each other. The plurality of first unit regions A1 may have the same shape and the plurality of second unit regions A2 may have the same shape.

The template substrate TS may include an independent third seed region J3 with a third direction D3, different from the first direction D1 and the second direction D2, being a longitudinal shape. An island-shaped third nitride semiconductor portion 8T may be disposed so as to extend from a third seed region J3 upward beyond the growth suppression region SP.

As illustrated in FIG. 3C, the mask pattern 6 may include an independent third opening portion K3 with the third direction D3 being a longitudinal shape, and the upper surface of the base substrate BS may include the third seed region J3 overlapping the third opening portion K3.

The third direction D3 is a direction different from the first and second directions D1 and D2 on the plane parallel to the base substrate BS, and a direction orthogonal to the third direction D3 on this plane is denoted by Y3.

The third nitride semiconductor portion 8T may be a hexagonal crystal, and the first direction D1 and the third direction D3 may form an acute angle of 60 degrees.

The template substrate TS may include one or more third unit regions A3 in which a plurality of independent opening portions including the third seed region J3 with the third direction D3 being a longitudinal shape are arranged. In the template substrate TS, a plurality of the third unit regions A3 may be dispersedly arranged in a plane. In this case, the third unit regions A3 may be arranged without being adjacent to each other.

In the semiconductor substrate 10, the plurality of longitudinal-shaped seed regions J may be formed on the template substrate TS including a heterogeneous substrate (the main substrate including a substrate material other than a nitride semiconductor), with the longitudinal directions not being aligned in a substrate plane (not being a single direction) and not intersecting with each other, and the nitride semiconductor portion 8 laterally grown from the seed regions J may be in an independent island shape. Compared with a case where the longitudinal directions of the seed regions J are a single direction and large warpage occurs in the single direction, the substrate warpage is dispersed in a plurality of directions, meaning that the absolute value of the warpage is reduced. Since the warpage occurs in a plurality of directions, the warpage can be effectively reduced by a strain relaxation layer structure of the base substrate BS. When the plurality of seed regions J intersect with each other, abnormal growth (for example, horn-shaped swelling) may occur in the semiconductor crystal grown from the intersecting portion. In view of this, by forming each seed region J into an independent shape, such abnormal growth can be avoided.

The first and second nitride semiconductor portions 8F and 8S may each have a tapered end portion. With the ELO for a nitride semiconductor crystal (for example, GaN), the a-axis direction is the growth direction, the m-axis direction is the stable direction (non-growth direction), and an m-plane extends from both ends of the nitride semiconductor crystal. Therefore, the nitride semiconductor portion 8 obtained by stopping the ELO while an a-plane of the nitride semiconductor crystal is exposed will have a tapered shape.

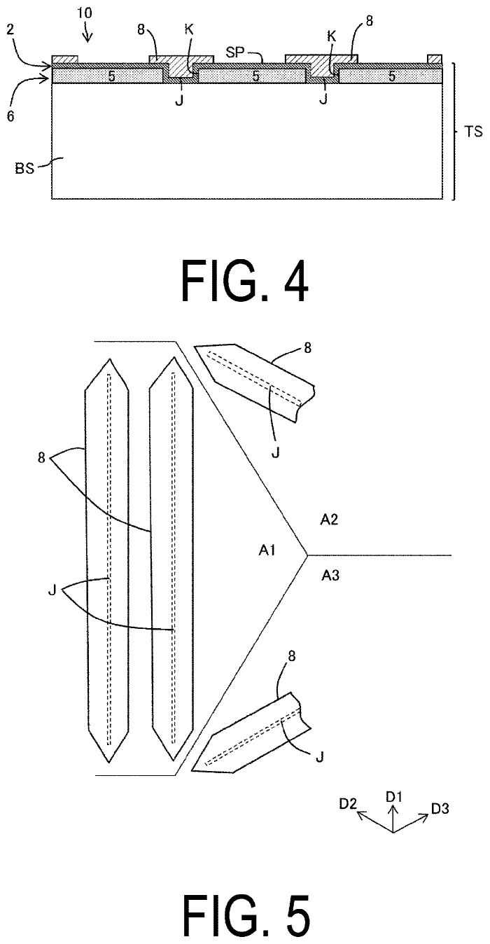

FIG. 4 is a cross-sectional view illustrating a configuration of another semiconductor substrate according to the present embodiment. As illustrated in FIG. 4, in the template substrate TS, a buffer portion 2 may be provided so as to cover the mask pattern 6. A highly reactive AlGaN film can be used for the buffer portion 2. In this case, the upper surface of the buffer portion 2 (AlGaN film) includes the growth suppression region SP overlapping the mask portion 5 in plan view and the seed region J overlapping the opening portion K in plan view. In the upper surface (AlGaN film surface) of the buffer portion 2, a region located above the mask portion 5 has low crystallinity and thus functions as the growth suppression region SP. On the other hand, a region located above the opening portion K (above the exposed portion of the base substrate BS) has high crystallinity and thus functions as the seed region J.

FIG. 5 is an enlarged plan view of a part of FIG. 2. As illustrated in FIGS. 2 and 5, each of the plurality of first unit regions A1, the plurality of second unit regions A2, and the plurality of third unit regions A3 may have a regular hexagonal shape, one of two adjacent sides of the first unit region A1 may oppose one side of the second unit region A2, another one of the sides may oppose one side of the third unit region A3, the first direction D1 may be orthogonal to a pair of opposite sides of the first unit region A1, and each of acute angles formed between the first direction D1 and the second direction D2 and between the first direction D1 and the third direction D3 may be 60°.

The plurality of seed regions J including the first seed region J1, extending in the same direction, and having the same length may be formed in the first unit region A1, the plurality of seed regions J including the second seed region J2, extending in the same direction, and having the same length may be formed in the second unit region A2, and the plurality of seed regions J including the third seed region J3, extending in the same direction, and having the same length may be formed in the third unit region A3.

The plurality of nitride semiconductor portions 8 including the first nitride semiconductor portion 8F, extending in the same direction, and having the same length may be formed on the first unit region A1, the plurality of nitride semiconductor portions 8 including the second nitride semiconductor portion 8S, extending in the same direction, and having the same length may be formed on the second unit region A2, and the plurality of nitride semiconductor portions 8 including the third nitride semiconductor portion 8T, extending in the same direction, and having the same length may be formed on the third unit region A3. In this case, since many nitride semiconductor portions 8 extending in the same direction and having the same length can be formed, excellent mass productivity of the semiconductor element using the nitride semiconductor portion 8 is achieved.

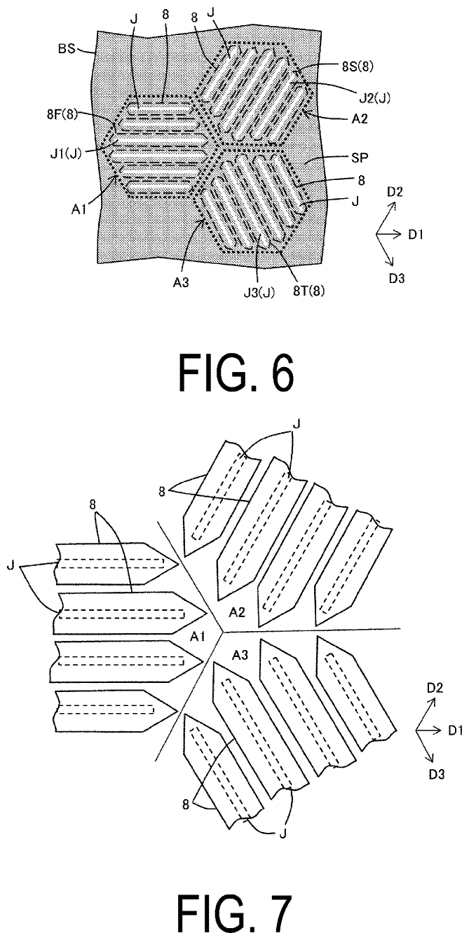

FIG. 6 is a plan view illustrating another configuration example of the semiconductor substrate according to the present embodiment. FIG. 7 is an enlarged plan view of a part of FIG. 6. As illustrated in FIGS. 6 and 7, each of the plurality of first unit regions A1, the plurality of second unit regions A2, and the plurality of third unit regions A3 may have a regular hexagonal shape, one of two adjacent sides of the first unit region A1 may oppose one side of the second unit region A2, another one of the sides may oppose one side of the third unit region A3, the first direction D1 may be parallel to a pair of opposite sides of the first unit region A1, and each of acute angles formed between the first direction D1 and the second direction D2 and between the first direction D1 and the third direction D3 may be 60°.

The plurality of seed regions J including the first seed region J1, extending in the same direction, and having a plurality of types of lengths may be formed in the first unit region A1, the plurality of seed regions J including the second seed region J2, extending in the same direction, and having a plurality of types of lengths may be formed in the second unit region A2, and the plurality of seed regions J including the third seed region J3, extending in the same direction, and having a plurality of types of lengths may be formed in the third unit region A3.

The plurality of nitride semiconductor portions 8 including the first nitride semiconductor portion 8F, extending in the same direction, and having a plurality of types of lengths may be formed on the first unit region A1, the plurality of nitride semiconductor portions 8 including the second nitride semiconductor portion 8S, extending in the same direction, and having a plurality of types of lengths may be formed on the second unit region A2, and the plurality of nitride semiconductor portions 8 including the third nitride semiconductor portion 8T, extending in the same direction, and having a plurality of types of lengths may be formed on the third unit region A3. In this case, the nitride semiconductor crystal can be grown to the vicinity of the edge of each unit region without waste, whereby the crystal yield can be increased. The long nitride semiconductor portion 8 can be formed in a center portion of the unit region.

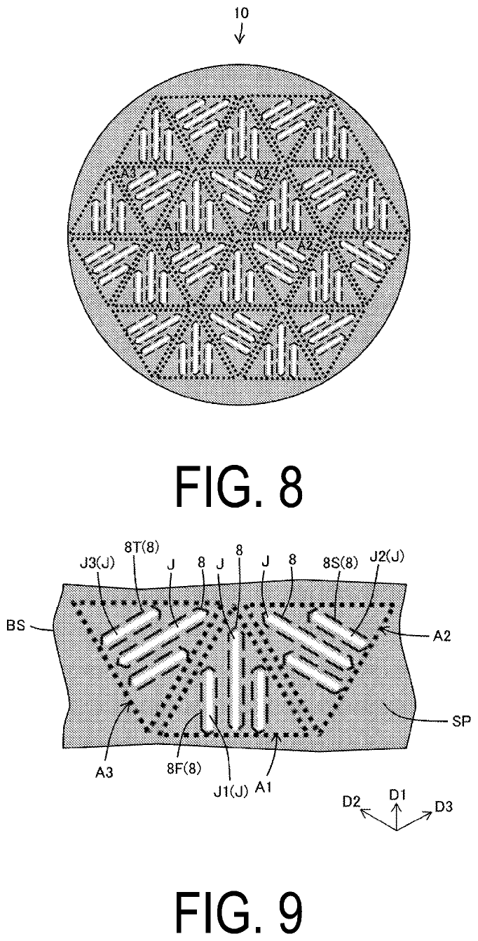

FIG. 8 is a plan view illustrating another configuration example of the semiconductor substrate according to the present embodiment. FIG. 9 is an enlarged plan view of a part of FIG. 8. As illustrated in FIGS. 8 and 9, each of the plurality of first unit regions A1, the plurality of second unit regions A2, and the plurality of third unit regions A3 may have an equilateral triangle shape, one of two adjacent sides of the first unit region A1 may oppose one side of the second unit region A2, another one of the sides may oppose one side of the third unit region A3, the first direction D1 may be parallel to a direction bisecting the angle formed between two adjacent sides of the first unit region A1, and each of acute angles formed between the first direction D1 and the second direction D2 and between the first direction D1 and the third direction D3 may be 60°.

The plurality of seed regions J including the first seed region J1, extending in the same direction, and having a plurality of types of lengths may be formed in the first unit region A1, the plurality of seed regions J including the second seed region J2, extending in the same direction, and having a plurality of types of lengths may be formed in the second unit region A2, and the plurality of seed regions J including the third seed region J3, extending in the same direction, and having a plurality of types of lengths may be formed in the third unit region A3.

The plurality of nitride semiconductor portions 8 including the first nitride semiconductor portion 8F, extending in the same direction, and having a plurality of types of lengths may be formed on the first unit region A1, the plurality of nitride semiconductor portions 8 including the second nitride semiconductor portion 8S, extending in the same direction, and having a plurality of types of lengths may be formed on the second unit region A2, and the plurality of nitride semiconductor portions 8 including the third nitride semiconductor portion 8T, extending in the same direction, and having a plurality of types of lengths may be formed on the third unit region A3.

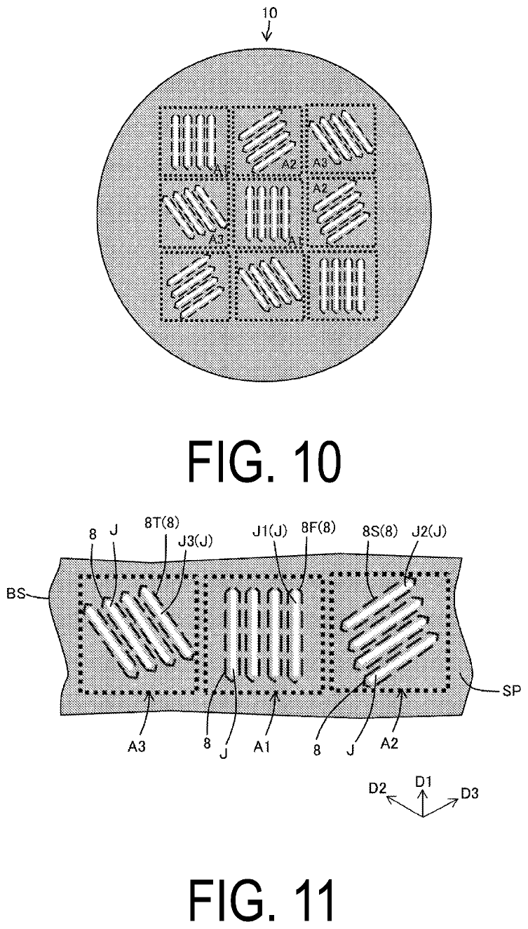

FIG. 10 is a plan view illustrating another configuration example of the semiconductor substrate according to the present embodiment. FIG. 11 is an enlarged plan view of a part of FIG. 10. As illustrated in FIGS. 10 and 11, each of the plurality of first unit regions A1, the plurality of second unit regions A2, and the plurality of third unit regions A3 may have a square shape, one of two opposite sides of the first unit region A1 may oppose one side of the second unit region A2, another one of the sides may oppose one side of the third unit region A3, the first direction D1 may be parallel to two opposite sides of the first unit region A1, and each of acute angles formed between the first direction D1 and the second direction D2 and between the first direction D1 and the third direction D3 may be 60°.

The plurality of seed regions J including the first seed region J1, extending in the same direction, and having the same length may be formed in the first unit region A1, the plurality of seed regions J including the second seed region J2, extending in the same direction, and having the same length may be formed in the second unit region A2, and the plurality of seed regions J including the third seed region J3, extending in the same direction, and having the same length may be formed in the third unit region A3.

The plurality of nitride semiconductor portions 8 including the first nitride semiconductor portion 8F, extending in the same direction, and having the same length may be formed on the first unit region A1, the plurality of nitride semiconductor portions 8 including the second nitride semiconductor portion 8S, extending in the same direction, and having the same length may be formed on the second unit region A2, and the plurality of nitride semiconductor portions 8 including the third nitride semiconductor portion 8T, extending in the same direction, and having the same length may be formed on the third unit region A3.

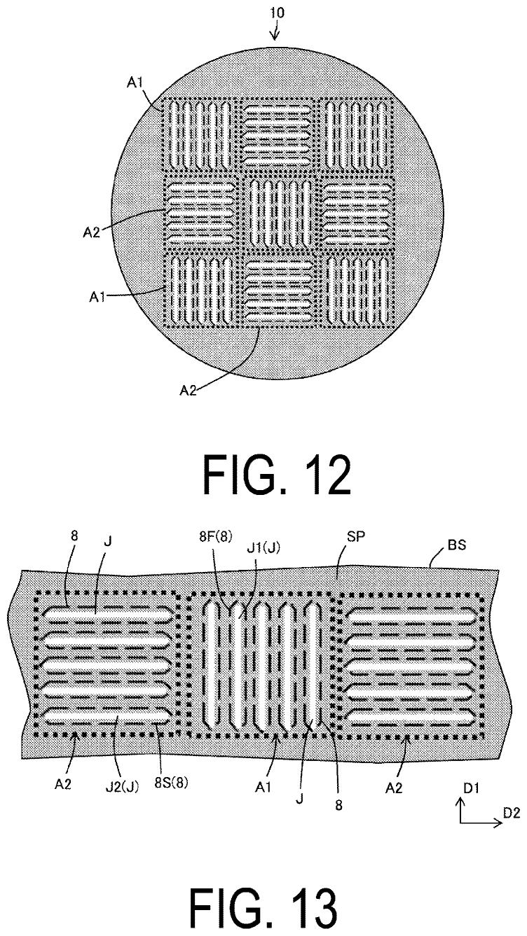

FIG. 12 is a plan view illustrating another configuration example of the semiconductor substrate according to the present embodiment. FIG. 13 is an enlarged plan view of a part of FIG. 12. As illustrated in FIGS. 12 and 13, each of the plurality of first unit regions A1 and the plurality of second unit regions A2 may have a square shape, one of two opposite sides of the first unit region A1 may oppose one side of the second unit region A2, the first direction D1 may be parallel to two opposite sides of the first unit region A1, and an angle formed between the first direction D1 and the second direction D2 may be 90°.

The plurality of seed regions J including the first seed region J1, extending in the same direction, and having the same length may be formed in the first unit regions A1, and the plurality of seed regions J including the second seed region J2, extending in the same direction, and having the same length may be formed in the second unit region A2.

The plurality of nitride semiconductor portions 8 including the first nitride semiconductor portion 8F, extending in the same direction, and having the same length may be formed on the first unit region A1, and the plurality of nitride semiconductor portions 8 including the second nitride semiconductor portion 8S, extending in the same direction, and having the same length may be formed on the second unit region A2.

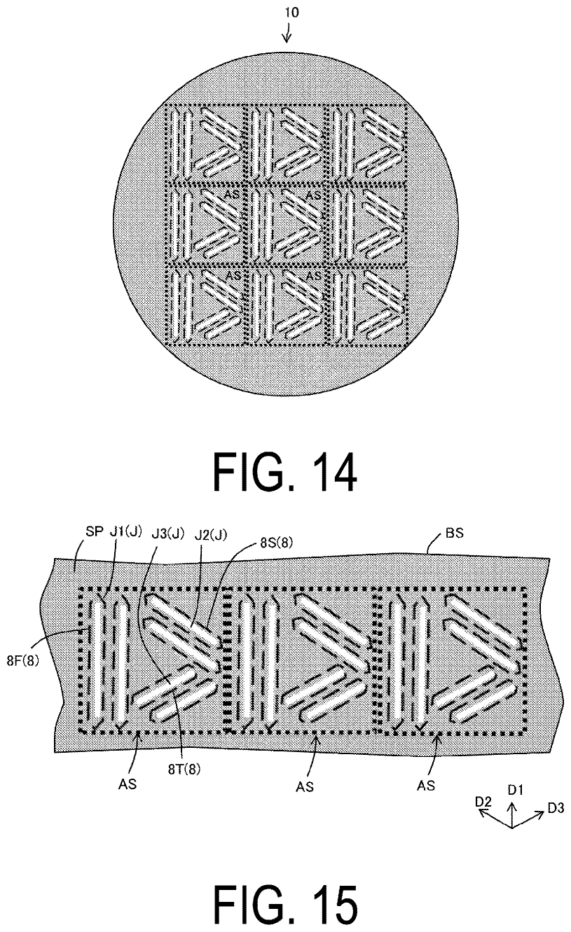

FIG. 14 is a plan view illustrating another configuration example of the semiconductor substrate according to the present embodiment. FIG. 15 is an enlarged plan view of a part of FIG. 14. As illustrated in FIGS. 14 and 15, the mask pattern 6 may have one or more unit regions AS in which the first seed region J1 and the second seed region J2 are arranged, the island-shaped first nitride semiconductor portion 8F may be disposed so as to extend from the first seed region J1 upward beyond the growth suppression region SP, and the island-shaped second nitride semiconductor portion 8S may be disposed so as to extend from the second seed region J2 upward beyond the growth suppression region SP. In the template substrate TS, a plurality of the unit regions AS may be arranged in matrix in a plane.

In the unit region AS, an independent third seed region J3 with a third direction D3, different from the first direction D1 and the second direction D2, being a longitudinal shape may be arranged. An island-shaped third nitride semiconductor portion 8T may be disposed so as to extend from a third seed region J3 upward beyond the growth suppression region SP. Each of the acute angles formed between the first direction D1 and the second direction D2 and between the first direction D1 and the third direction D3 may be 60°.

In the unit region AS, the plurality of seed regions J having the same size, including the first seed region J1, and extending in the first direction D1, the plurality seed regions J having the same size, including the second seed region J2, and extending in the second direction D2, and a plurality of opening portions having the same size, including the third seed region J3, and extending in the third direction D3 may be formed.

On the unit region AS, the plurality of nitride semiconductor portions 8 having the same size, including the first nitride semiconductor portion 8F, and extending in the first direction D1, the plurality of nitride semiconductor portions 8 having the same size, including the second nitride semiconductor portion 8S, and extending in the second direction D2, and the plurality of nitride semiconductor portions 8 having the same size, including the third nitride semiconductor portion 8T, and extending in the third direction D3 may be formed.

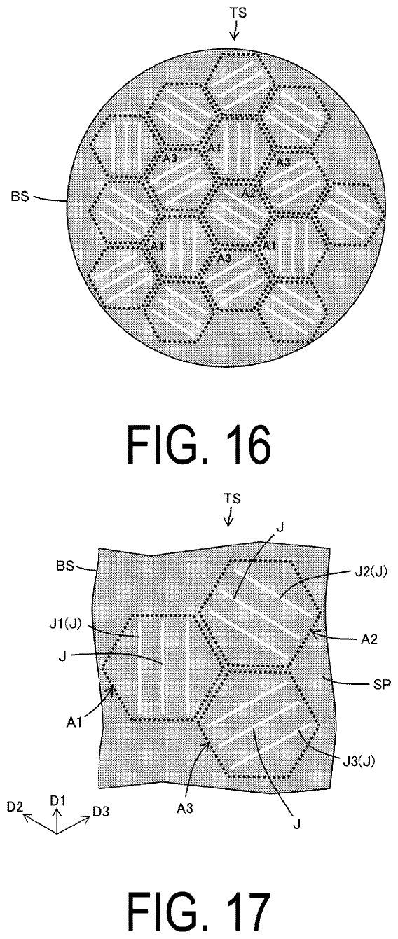

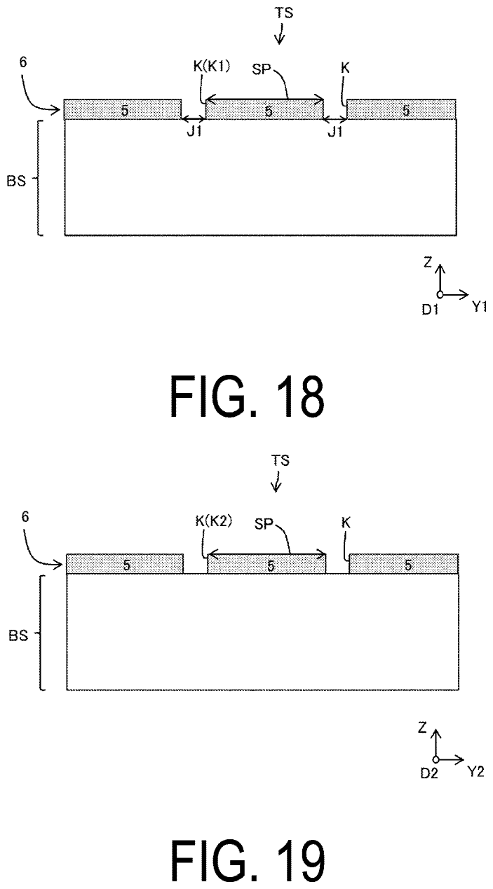

Template Substrate FIG. 16 is a plan view illustrating a configuration example of a template substrate according to the present embodiment FIG. 17 is an enlarged plan view of a part of FIG. 16. FIG. 18 and FIG. 19 are cross-sectional views illustrating a configuration example of the template substrate according to the present embodiment. As illustrated in FIGS. 16 to 19, the template substrate TS according to the present embodiment includes the base substrate BS, as well as the mask pattern 6 including the growth suppression region SP, the independent first seed region J1 with the first direction D1 being the longitudinal direction, and the independent second seed region J2 with the second direction D2, different from the first direction D1, being the longitudinal direction. The first and second directions D1 and D2 are, for example, different directions on a plane parallel to the base substrate BS. On this plane, a direction orthogonal to the first direction D1 is denoted by Y1, a direction orthogonal to the second direction D2 is denoted by Y2, and a normal direction of this plane is denoted by Z. The template substrate TS may have on the base substrate BS, a mask portion 5 and a mask pattern 6 including a first opening portion K1 and a second opening portion K2, the growth suppression region SP may be an upper surface of the mask portion 5, and the base substrate BS may have an upper surface including the first seed region J1 overlapping the first opening portion K1 and the second seed region J2 overlapping the second opening portion K2.

The template substrate TS may include: one or more first unit regions A1 in which a plurality of the independent seed regions J including the first seed region J1 with the first direction D1 being a longitudinal direction are arranged; and one or more second unit regions A2 in which a plurality of the independent seed regions J including the second seed region J2 with the second direction D2 being a longitudinal direction are arranged. In the template substrate TS, as illustrated in FIG. 16, the plurality of first unit regions A1 may be dispersedly arranged in a plane, and the plurality of second unit regions A2 may be dispersedly arranged in the plane. The plurality of first unit regions A1 and the plurality of second unit regions A2 may be arranged without the first unit regions A1 being adjacent to each other and without the second unit regions A2 being adjacent to each other.

The template substrate TS may include an independent third seed region J3 with the third direction D3, different from the first direction D1 and the second direction D2, being the longitudinal shape. The mask pattern 6 may include an independent third opening portion K3 with the third direction D3 being a longitudinal shape, and the upper surface of the base substrate BS may include the third seed region J3 overlapping the third opening portion K3.

The plurality of first unit regions A1 may have the same shape and the plurality of second unit regions A2 may have the same shape. The template substrate TS may include one or more third unit regions A3 in which a plurality of independent seed regions J including the third seed region J3 with the third direction D3 being a longitudinal shape are arranged. In the template substrate TS, a plurality of the third unit regions A3 may be dispersedly arranged in a plane. In this case, the third unit regions A3 may be arranged without being adjacent to each other.

### Manufacturing Method and Manufacturing Apparatus

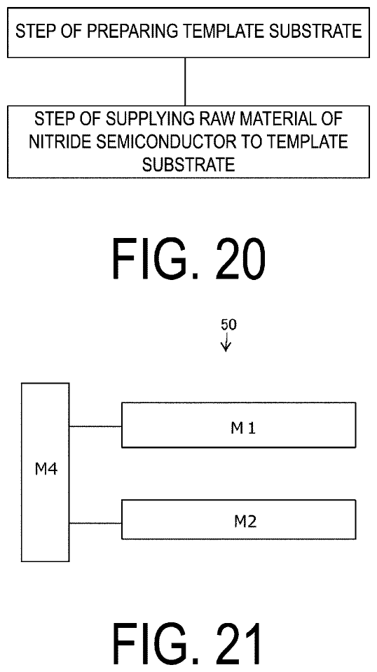

FIG. 20 is a flowchart illustrating a manufacturing method of a semiconductor substrate according to the present embodiment. As illustrated in FIG. 20, the manufacturing method of a semiconductor substrate according to the present embodiment includes preparing the template substrate TS and supplying a raw material of a nitride semiconductor to the template substrate TS rotating with a substrate normal line being a rotation axis.

FIG. 21 is a block diagram illustrating a manufacturing apparatus of a semiconductor substrate according to the present embodiment. As illustrated in FIG. 21, the manufacturing method of the semiconductor substrate according to the present embodiment includes an apparatus M1 configured to prepare the template substrate TS, and an apparatus M2 (nitride semiconductor forming apparatus) configured to supply a raw material of a nitride semiconductor to the template substrate TS rotating with a substrate normal line being a rotation axis.

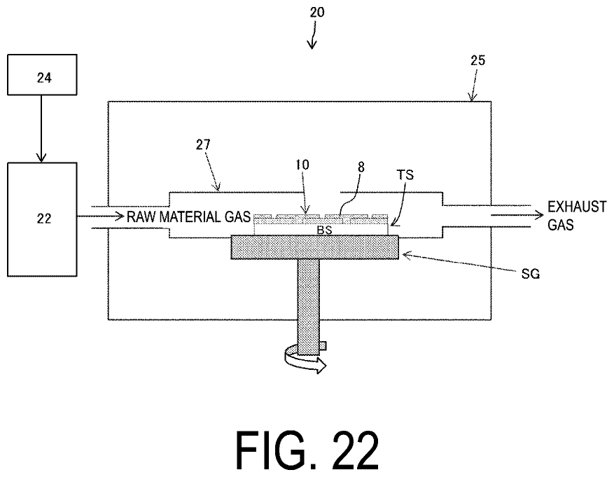

FIG. 22 is a schematic view illustrating a configuration of a nitride semiconductor forming apparatus according to the present embodiment. As illustrated in FIG. 22, the manufacturing apparatus 20 of the semiconductor substrate includes a stage 21 on which the template substrate TS including the base substrate BS, the growth suppression region SP, and the seed region J is placed, a raw material supply device 22 configured to supply a raw material for growing the nitride semiconductor portion 8 on the template substrate TS, and a control device 24 configured to control the raw material supply device 22. The manufacturing apparatus 20 of the semiconductor substrate may be provided with a chamber 25 including a stage SG, a flow channel 27 passing through the chamber 25, and a heating device 26 for heating the chamber 25, and the semiconductor substrate 10 may be disposed in the flow channel 27.

The stage 21 may perform a rotation operation (with an axis in the normal direction of the template substrate TS being a rotation axis). In FIG. 21, the raw material supply device 22 causes a raw material gas to flow laterally (in a direction parallel to the upper surface of the template substrate) in the flow channel 27 to perform lateral exhaust; however, the present disclosure is not limited thereto. The raw material gas may flow in a vertical direction (normal direction of the template substrate TS).

### Example 1

### Base Substrate

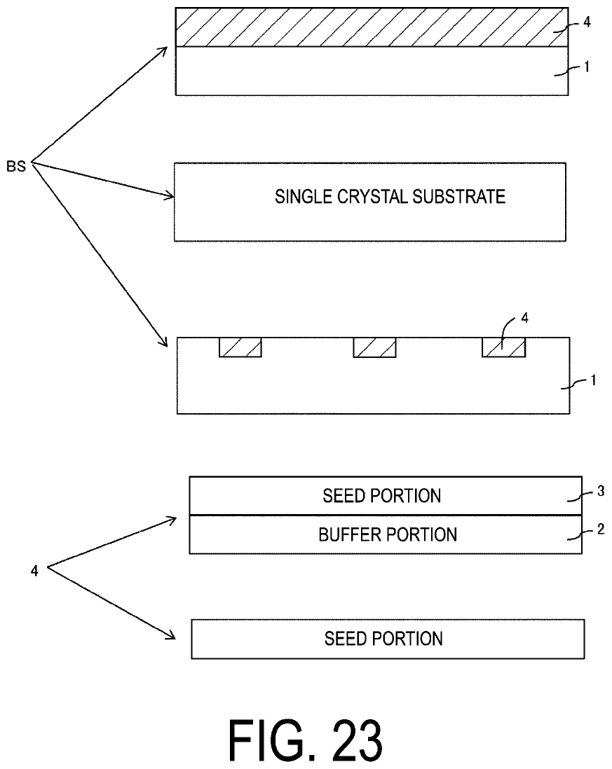

FIG. 23 is a cross-sectional view illustrating a configuration example of a base substrate. The base substrate BS may include a main substrate 1 that is a heterogeneous substrate having a different lattice constant from the nitride semiconductor portion 8. The nitride semiconductor portion 8 may include a GaN-based semiconductor, and the main substrate 1, which is a heterogeneous substrate, may be a silicon substrate. In addition to the silicon substrate, examples of the heterogeneous substrate include a sapphire (Al₂O₃) substrate and a silicon carbide (SiC) substrate. The plane direction of the main substrate 1 is, for example, the (111) plane of the silicon substrate, the (0001) plane of the sapphire substrate, or the 6H—SiC (0001) plane of the SiC substrate. These are merely examples, and any substrate and any plane orientation may be used as long as the nitride semiconductor portion 8 can be grown by the ELO method.

The base substrate BS may include the main substrate 1 and the underlying part 4 on the main substrate 1, and the nitride semiconductor portion 8 may be grown from an upper surface (seed region J) of the underlying part 4 exposed at the opening portion K. The underlying portion 4 may include a GaN-based semiconductor. The underlying portion 4 may include a buffer portion 2 and/or a seed portion 3. As the buffer portion 2, a GaN-based semiconductor, AlN, SiC, or the like can be used. As the seed portion 3, a nitride semiconductor (for example, GaN-based semiconductor, AlN) may be used. The base substrate BS may be constituted by a freestanding single crystal substrate (for example, a wafer cut out from a bulk crystal) of SiC or the like, and the mask pattern 6 may be disposed on the single crystal substrate. The underlying portion 4 may not be formed on the entire surface of the main substrate 1, and may be locally provided so as to overlap the opening portion K in plan view (the underlying portion 4 is exposed from the opening portion K).

### Mask Pattern

The mask pattern 6 includes the mask portion 5 and the opening portion K. The opening portion K may function as a growth start hole that exposes the seed region J and starts the growth of the nitride semiconductor portion 8, and the mask portion 5 may function as a selective growth mask (deposition suppression mask) for growing the nitride semiconductor portion 8 in the lateral direction. Examples of the mask portion 5 that can be used include a single-layer film including any one of a silicon oxide film (SiOx), a titanium nitride film (TiN or the like), a silicon nitride film (SiNx), a silicon oxynitride film (SiON), and a metal film having a high melting point (for example, 1000° C. or higher), or a layered film including at least two thereof. A thermal oxide film obtained by performing thermal oxidation treatment on a silicon substrate, a silicon nitride substrate, or the like may be used as the mask portion 5.

As the mask portion 5, a laminated film in which a silicon oxide film and a silicon nitride film are formed in this order can be used. Since the nitride semiconductor portion 8 and the mask portion 5 may react with each other and adhere to each other depending on film formation conditions, an upper layer film in direct contact with the nitride semiconductor portion 8 may be a silicon nitride film. In a process of locally forming the seed portion 3, a film on the support substrate 1 (lower layer film) may be removed, and the use of a silicon oxide film, from which the film on the support substrate 1 can be easily completely removed, as a lower layer film also has an effect of improving the yield of the process.

### Film Formation of Nitride Semiconductor Portion

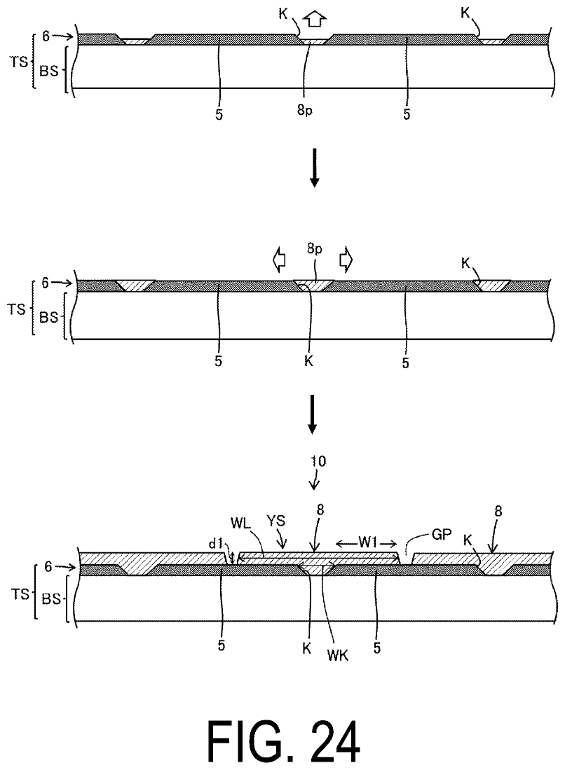

FIG. 24 is a cross-sectional view illustrating a manufacturing method of a semiconductor substrate according to Example 1. In Example 1, the nitride semiconductor portion 8 was a GaN layer, and ELO film formation was performed on the above-described template substrate TS by using an MOCVD device included in the apparatus M2 (nitride semiconductor forming apparatus) of FIG. 21. The following may be adopted as examples of the ELO film formation conditions: substrate temperature: 1120° C., growth pressure: 50 kPa, trimethylgallium (TMG): 22 sccm, NH₃: 15 slm, and V/III=6000 (ratio of group V raw material supply amount to group III raw material supply amount).

An initial growth portion 8p serves as a starting point of the lateral direction growth of the nitride semiconductor portion 8. The initial growth layer 8p can be formed to have a thickness of, for example, 30 nm to 1000 nm, 50 nm to 400 nm, or 70 nm to 350 nm. By implementing the lateral growth from the state in which the initial growth portion 8p slightly protrudes from the mask portion 5, growth of the nitride semiconductor portion 8 in the c-axis direction (thickness direction) can be suppressed, the nitride semiconductor portion 8 can be laterally grown at a high speed and high crystallinity, and consumption of raw materials is also reduced. Thus, the nitride semiconductor portion 8 (crystalline body of the nitride semiconductor such as GaN) having a low number of defects can be formed in thin and wide manner at a low cost.

The nitride semiconductor portions 8 laterally grown in opposite directions from two adjacent opening portions K do not make contact with (do not meet) each other on the mask portion 5 but have a gap GP therebetween, thereby making it possible to reduce an internal stress in the nitride semiconductor portion 8. Thus, cracks and defects (dislocations) occurring in the nitride semiconductor portion 8 can be reduced. This effect is particularly exhibited when the main substrate 1 is a heterogeneous substrate. The width of the gap GP can be, for example, 10 μm or less, 5 μm or less, 3 μm or less, or 2 μm or less.

In the nitride semiconductor portion 8, a portion located on the initial growth portion 8p serves as a dislocation inheritance portion in which a great number of threading dislocations occur, and a portion (wing portion) on the mask portion 5 serves as a low-defect portion YS where a threading dislocation density is 1/10 or less compared to the dislocation inheritance portion. The threading dislocation is a dislocation (defect) extending in the nitride semiconductor portion 8 in the c-axis direction <0001> direction. The threading dislocation density of the low-defect portion YS can be set to, for example, 5×10⁶ [/cm²] or less. As described below, when an active portion (active layer) including a light-emitting portion is formed above the nitride semiconductor portion 8, the light-emitting portion can be disposed above the low-defect portion YS (to overlap the low-defect portion YS in plan view).

Regarding the low-defect portion YS, a ratio (W1/d1) of a size W1 in the a-axis direction to a thickness d1 may be set to 2.0 or more, for example. Using the method of Example 1 makes it possible to set W1/d1 to 1.5 or more, 2.0 or more, 4.0 or more, 5.0 or more, 7.0 or more, or 10.0 or more. With W1/d1 set to be 1.5 or more, the internal stress in the nitride semiconductor portion 8 is reduced and the warpage of the semiconductor substrate 10 is reduced.

The aspect ratio of the nitride semiconductor portion 8 (ratio of a size in the X direction to the thickness=WL/d1) can be set to 3.5 or more, 5.0 or more, 6.0 or more, 8.0 or more, 10 or more, 15 or more, 20 or more, 30 or more, or 50 or more. Using the method of Example 1 makes it possible to set the ratio WL/WK of the size WL in the X direction of the nitride semiconductor portion 8 to a width WK of the opening portion K to 3.5 or more, 5.0 or more, 6.0 or more, 8.0 or more, 10 or more, 15 or more, 20 or more, 30 or more, or 50 or more, and makes it possible to increase the ratio of the low-defect portion. The nitride semiconductor portion 8 (including the initial growth portion 8p) illustrated in FIG. 24 can be a nitride semiconductor crystal (for example, a GaN crystal, an AlGaN crystal, an InGaN crystal, or an InAlGaN crystal).

### Example 2

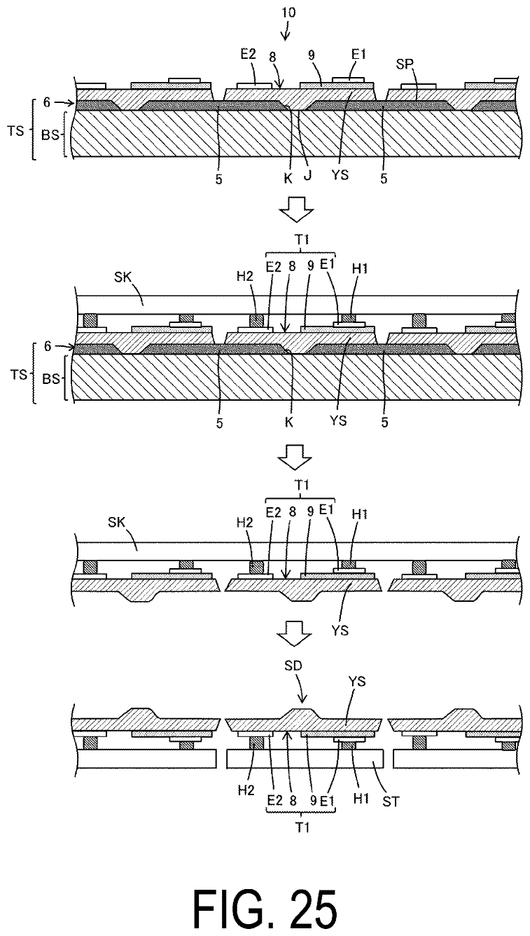

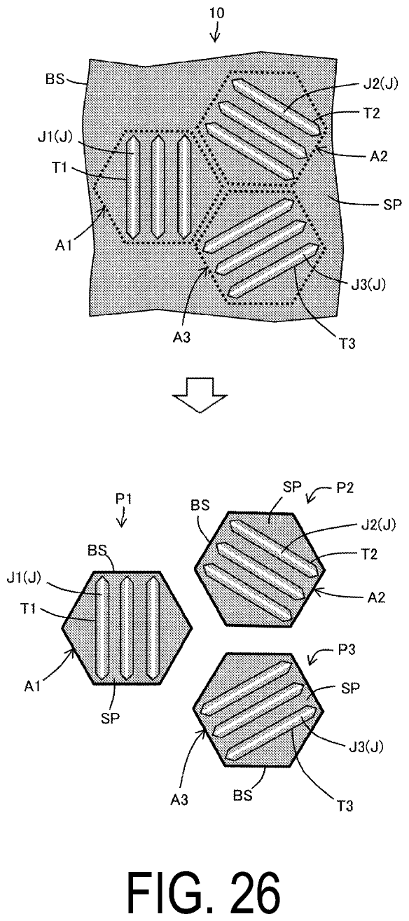

FIG. 25 is a cross-sectional view illustrating a manufacturing method of a semiconductor element according to a second example. FIG. 26 is a plan view illustrating a manufacturing method of a semiconductor element according to Example 2. In FIG. 25, the manufacturing method includes a step of, after preparing the semiconductor substrate 10, forming a compound semiconductor portion 9 and electrodes E1 and E2 on the semiconductor substrate 10, a step of joining a layered body T1 including the nitride semiconductor portion 8, the compound semiconductor portion 9, and the electrodes E1 and E2 to a support substrate SK via joining layers H1 and H2, a step of peeling off the base substrate BS, and a step of singulating the support substrate SK into a plurality of supports ST to form semiconductor elements SD holding the layered body T1 on the supports ST. Before peeling off the base substrate BS, the mask portion 5 may be removed by wet etching or the like. As illustrated in FIG. 26, after the compound semiconductor portion 9 and the electrodes E1 and E2 are formed, the semiconductor substrate 10 may be cut along the edges of the first to third unit regions A1 to A3 of the template substrate TS, to form a polygonal substrate P1 including a plurality of stacked bodies T1 on the first unit region A1, a polygonal substrate P2 including a plurality of stacked bodies T2 on the second unit region A2, and a polygonal substrate P3 including a plurality of stacked bodies T3 on the third unit region A3. In a case where the first to third unit regions A1 to A3 have the same shape, the polygonal substrates P1 to P3 also have the same structure, and thus the post-process is facilitated.

The nitride semiconductor portion 8 may be an n-type semiconductor crystal. The compound semiconductor portion 9 may include a GaN-based semiconductor. The compound semiconductor portion 9 may include an active portion (for example, an active layer having a quantum well structure or the like) and a p-type semiconductor portion, or may include an n-type semiconductor portion (for example, a regrowth layer or an n-type contact layer) under the active portion. When the active portion of the compound semiconductor portion 9 includes a light-emitting portion, the light-emitting portion can be disposed above the low-defect portion YS (to overlap the low-defect portion YS in plan view). Thus, the light emission efficiency can be increased.

The electrode E1 located above the low-defect portion YS may be an anode and the electrode E2 may be a cathode. The support substrate SK may have a conductive pad in contact with the joining layer H1 and a conductive pad in contact with the joining layer H2. The joining layers H1 and H2 may each be made of a solder material. Before, during, or after joining to the support substrate SK, the layered body T1 having a longitudinal shape may be divided into a plurality of pieces (by cutting in the short direction). In this case, the dividing step may be performed by cleaving the nitride semiconductor portion 8 and the compound semiconductor portion 9 (for example, m-plane cleavage in which a cleavage plane is an m-plane). In the case of forming a semiconductor laser element, end face coating (formation of a reflective mirror film) may be performed on the m-plane being the cleavage plane. Although the layered body T1 is transferred from the base substrate BS to the support substrate SK in FIG. 25, the present disclosure is not limited thereto. The layered body T1 may be transferred from the base substrate BS to a tape or the like one or more times.

Each semiconductor element SD may function as a light-emitting diode (LED) element or a semiconductor laser element. The support ST may be a sub-mount substrate. The second example includes an electronic device (for example, an illumination device, a laser device, a display device, a measurement device, an information processing device, or the like) including the semiconductor element SD.

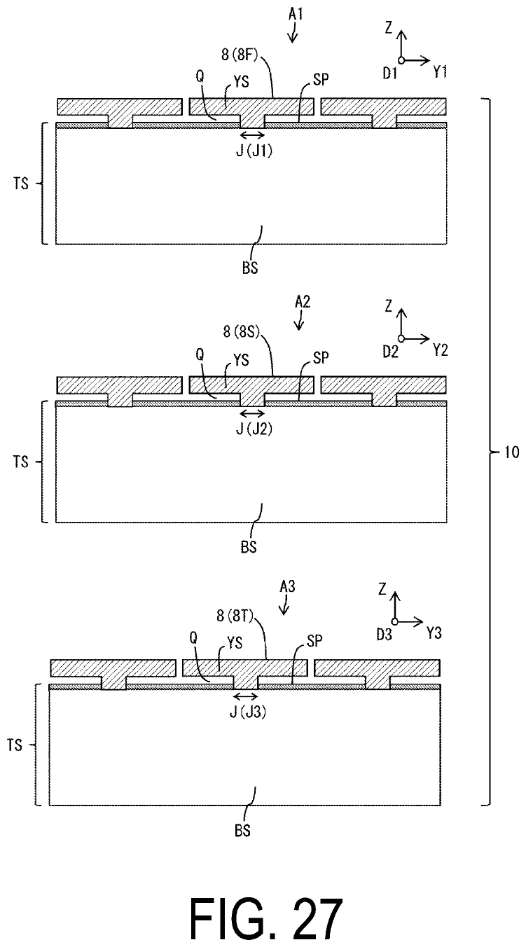

FIG. 27 is a cross-sectional view illustrating a configuration example of a semiconductor substrate according to the present embodiment. As illustrated in FIGS. 1 and 27, in each of the first unit region A1, the second unit region A2, and the third unit region A3, the low-defect portion (wing portion YS) of the nitride semiconductor portion 8 (8F, 8S, 8T) above the growth suppression region SP may be grown so as to be spaced apart from the growth suppression region SP. With the nitride semiconductor portion 8 thus grown to make the wing portion YS face the growth suppression region SP with a gap Q in between, the influence of the stress of the nitride semiconductor portion 8 is further reduced, and the warpage of the semiconductor substrate 10 including the nitride semiconductor portion 8 can be further suppressed. In FIG. 27, the seed region J (J1, J2, J3) is located on the lower side of the growth suppression region SP, but this is not to be construed in a limiting sense. The seed region J may be positioned to be flush with region SP or may be located on the upper side of the growth suppression region SP.

### Supplementary Note

The foregoing disclosure has been presented for purposes of illustration and description, and not limitation. It is noted that many variations will be apparent to those skilled in the art based on these illustrations and descriptions, and these variations are included in the embodiments.

### REFERENCE SIGNS

1 Main substrate
5 Mask portion
6 Mask pattern
SP Growth suppression region
8F First nitride semiconductor portion
8S Second nitride semiconductor portion
8T Third nitride semiconductor portion
10 Semiconductor substrate
20 Manufacturing apparatus of semiconductor substrate
BS Base Substrate
TS Template Substrate
A1 First unit region
A2 Second unit region
A3 Third unit region
D1 First direction
D2 Second direction
D3 Third direction
J1 First seed region
J2 Second seed region
J3 Third seed region
K1 First opening portion
K2 Second opening portion
K3 Third opening portion
YS Low-defect portion

1. A semiconductor substrate comprising:
a template substrate comprising a base substrate comprising a substrate material that is not a nitride semiconductor, the template substrate comprising a growth suppression region, a first seed region having a first direction as a longitudinal direction, and a second seed region having a second direction, different from the first direction, as a longitudinal direction, wherein the first seed region and the second seed region are independent from each other;
a first nitride semiconductor portion having an island-shape and arranged above the first seed region and the growth suppression region; and
a second nitride semiconductor portion having an island-shape and arranged above the second seed region and the growth suppression region.

2. The semiconductor substrate according to claim 1, wherein
the template substrate comprises a third seed region having a third direction, different from the first direction and the second direction, as a longitudinal shape, wherein the third seed region is independent from the first seed region and the second seed region, and
a third nitride semiconductor portion having an island-shape and arranged above the third seed region and the growth suppression region.

3. The semiconductor substrate according to claim 1, wherein
each of the first nitride semiconductor portion and the second nitride semiconductor portion is a hexagonal crystal, and
an acute angle formed between the first direction and the second direction is 60 degrees.

4. The semiconductor substrate according to claim 2, wherein
the third nitride semiconductor portion is a hexagonal crystal, and
an acute angle formed between the first direction and the third direction is 60 degrees.

5. The semiconductor substrate according to claim 1, wherein
the template substrate comprises:
one or more first unit regions in which a plurality of seed regions comprising the first seed region are arranged, each of the plurality of seed regions being independent and having a first direction being a longitudinal direction; and
one or more second unit regions in which a plurality of seed regions comprising the second seed region are arranged, each of the plurality of seed regions being independent and having a second direction being a longitudinal direction.

6. The semiconductor substrate according to claim 5, wherein in the template substrate, a plurality of the first unit regions are dispersedly arranged in a plane, and a plurality of the second unit regions are dispersedly arranged in the plane.

7. The semiconductor substrate according to claim 6, wherein first unit regions of the plurality of the first unit regions are not adjacent to each other, and second unit regions of the plurality of the second unit regions are not adjacent to each other.

8. The semiconductor substrate according to claim 6, wherein the plurality of the first unit regions and the plurality of the second unit regions each have an identical shape.

9. The semiconductor substrate according to claim 5, wherein the template substrate comprises one or more third unit regions in which a plurality of seed regions are arranged, each of the plurality of seed regions being independent and having a third direction, different from the first direction and the second direction, being a longitudinal shape.

10. The semiconductor substrate according to claim 9, wherein in the template substrate, a plurality of the third unit regions are dispersedly arranged in a plane.

11. The semiconductor substrate according to claim 8, wherein the identical shape is any one of an equilateral triangle, a square, and a regular hexagon.

12. The semiconductor substrate according to claim 11, wherein
the identical shape is a regular hexagon, with one side of a first unit region of the plurality of the first unit regions opposing one side of a second unit region of the plurality of the second unit regions,
the first direction is orthogonal to a pair of opposing sides of the first unit region, and an acute angle formed between the first direction and the second direction is 60°,
a plurality of seed regions comprising the first seed region are formed in the first unit region, the plurality of seed regions extending in an identical direction and having an identical length, and a plurality of seed regions comprising the second seed region are formed in the second unit region, the plurality of seed regions extending in an identical direction and having an identical length, and
a plurality of nitride semiconductor portions comprising the first nitride semiconductor portion are formed above the first unit region, the plurality of nitride semiconductor portions extending in an identical direction and having an identical length, and a plurality of nitride semiconductor portions comprising the second nitride semiconductor portion are formed above the second unit region, the plurality of nitride semiconductor portions extending in an identical direction and having an identical length.

13. The semiconductor substrate according to claim 11, wherein
the identical shape is a regular hexagon, with one side of a first unit region of the plurality of the first unit regions opposing one side of a second unit region of the plurality of the second unit regions,
the first direction is parallel to a pair of opposing sides of the first unit region, and an acute angle formed between the first direction and the second direction is 60°,
a plurality of seed regions comprising the first seed region are formed in the first unit region, the plurality of seed regions extending in an identical direction and having a plurality of types of lengths, and a plurality of seed regions comprising the second seed region are formed in the second unit region, the plurality of seed regions extending in an identical direction and having a plurality of types of lengths, and
a plurality of nitride semiconductor portions comprising the first nitride semiconductor portion are formed above the first unit region, the plurality of nitride semiconductor portions extending in an identical direction and having a plurality of types of lengths, and a plurality of nitride semiconductor portions comprising the second nitride semiconductor portion are formed above the second unit region, the plurality of nitride semiconductor portions extending in an identical direction and having a plurality of types of lengths.

14. The semiconductor substrate according to claim 1, wherein the template substrate comprises one or more unit regions in which the first seed region and the second seed region are arranged.

15. The semiconductor substrate according to claim 14, wherein in the template substrate, a plurality of the unit regions are arranged in a matrix in a plane.

16. The semiconductor substrate according to claim 14, wherein in each of the plurality of the unit regions, a third seed region is arranged, the third seed region being independent and having a third direction, different from the first direction and the second direction, being a longitudinal shape.

17. The semiconductor substrate according to claim 1, wherein
the first direction is a <1-100> direction of the first nitride semiconductor portion, and
the second direction is the <1-100> direction of the second nitride semiconductor portion.

18. (canceled)

19. The semiconductor substrate according to claim 1, wherein the first nitride semiconductor portion and the second nitride semiconductor portion each have a tapered end portion.

20. (canceled)

21. The semiconductor substrate according to claim 1, wherein the first nitride semiconductor portion and the second nitride semiconductor portion comprise a GaN-based semiconductor and the substrate material having a different lattice constant from that of the first nitride semiconductor portion.

22. (canceled)

23. The semiconductor substrate according to claim 1, wherein
the template substrate comprises a mask pattern comprising a mask portion, a first opening portion being independent and having the first direction being a longitudinal direction, and a second opening portion being independent and having the second direction being a longitudinal direction,
an upper surface of the mask portion is the growth suppression region, and
the first seed region overlapping the first opening portion and the second seed region overlapping the second opening portion are comprised in an upper surface of the base substrate.

24. (canceled)

25. (canceled)

26. (canceled)
